(19) United States
(12) Patent Application Publication
(10) Pub. No.: US 2005/0269580 A1
(43) Pub. Date: Dec. 8, 2005

(54) Single wire serial protocol for RGB LED drivers

(76) Inventor: Kevin P. D'Angelo, Santa Clara, CA (US)

Correspondence Address: ADVANCED ANALOGIC TECHNOLOGIES, 830 EAST ARQUES AVE, SUNNYVALE, CA, 94085, US

(21) Appl. No.: 10/860,913

(22) Filed: Jun. 4, 2004

(51) Int. Cl. H01L 29/18

(52) U.S. Cl. 257/88

(57) ABSTRACT

A method for RGB LED control includes toggling the voltage on a serial line to encode desired colors as a repeating series of variable width pulses. Each pulse in the series corresponds to red, green or blue colors. A state machine monitors the serial line and separates the repeating series into red, green and blue pulses. The state machine forwards each separate pulse to the corresponding color element of an RGB LED. In effect, this provides each color element with a separate PWM control signal. A synchronization method is provided to ensure that the state machine correctly decodes the repeating sequence of red, green and blue colors.

### TECHNICAL FIELD

The present invention relates to drivers used to power light emitting diodes (LEDs) and other devices. More particularly, the present invention relates to efficient drivers for RGB LED applications in portable electronic systems.

### BACKGROUND OF THE INVENTION

RGB LEDs are used in a wide range of portable electronic devices including cellular telephones, personal digital assistants and handheld games. A typical RGB LED includes separate red, green and blue light emitting diodes. The separate diodes are driven for different duty cycles (typically in series, one after the other) to generate different colors. A simple case is where red, green and blue diodes are each driven for the same period in succession to create the color white.

To maximize battery life, it is typical for portable electronic devices to use specialized LED drivers. Drivers of this type supply LEDs with regulated power at the correct voltage even as battery voltage fluctuates or declines. LED drivers can also provide other functions such as variable brightness (dimming) and color control for RGB LEDs.

LED drivers are typically implemented as small standalone integrated circuits. The packages used for these implementations typically have a small number of leads or pins. As a result, it is very desirable to design LED drivers in a way that minimizes the number of leads that are used to control their operation. In some cases, this has been accomplished by using analog signals to reduce the number of leads required for control purposes. This is particularly attractive where a function or output is controlled over a range of values (as may be the case where an LED driver provides for variable brightness). In cases of this type, a single analog input can be used to control the function or output. Unfortunately, the use of analog signals is inherently error prone and not always easy to calibrate. It is also true that many microprocessors lack analog outputs, making implementation of analog control signals even more difficult.

Digital control systems are also possible, and may be implemented to pass data serially or in parallel. The digital nature of these systems increases their compatibility with microprocessors. However, even serial implementations typically require at least two (and often three) inputs leads. Where input leads are scarce, the use of two to three leads may be difficult to accommodate. In other cases, the use of two or three input signals may create complex routing problems between the driver and its controlling entity.

U.S. patent application Ser. No. 10/144,333 (incorporated in this document by reference) describes a single wire serial interface for power control and other devices. For this protocol, a master device uses a single wire to communicate with a slave device. To send a command to the slave, the master device toggles the voltage on the serial line. The slave counts the number of voltage transitions on the serial line and enters an operational state that corresponds to that number. The master device can then cause the device to maintain its operational state by holding the voltage on the serial line high. Alternately, by holding the voltage low for a predetermined timeout period, the master causes the slave device to reset. As an example, consider an LED driver that supports 64 levels of brightness as well as an off state. To control a device of this type using the single wire serial interface, a master device would choose the brightness level desired and cause the voltage on the serial line to toggle that many times. Toggling the voltage 39 times would, for example, select the 39^{th} brightness level. Holding the serial line high would cause the previously defined brightness level to be maintained. Holding the serial line low would cause the LED driver to turn the LED off.

U.S. patent application Ser. No. 10/447,764 (incorporated in this document by reference) describes a method for using the single wire serial protocol to drive an RGB LED. For that method, the master device sends a repeating series of signals corresponding to red, green and blue colors. A state machine demultiplexes the series of signals, using the red signals to drive the red LED, the green signals to drive the green LED and the blue signals to drive the blue LED. By tailoring the individual red, green and blue signals, the master device can control the color produced by the RGB LED.

For the approach just described, the state machine demultiplexes the separate color signals by detecting the end of each signal. Each detection causes the state machine to redirect the following signal to the next LED (i.e., from red to green, green to blue, or blue to red). This has the advantage of making the state machine relatively easy to implement if not entirely robust. In particular, there is a possibility that a missed detection may result in a situation where demultiplexing preceded incorrectly and colors are incorrectly reproduced.

For these reasons, there is a need for improved methods for controlling RGB LED drivers. This is particularly important in high noise environments where errors are more likely to occur.

### SUMMARY OF THE INVENTION

The present invention provides a method for RGB LED control using a single wire serial interface. For the control method, a master device controls the voltage on a serial line to encode a repeating series of variable width pulses. Each pulse in the series corresponds to red, green or blue colors. The red, green and blue pulses are interleaved in a repeating pattern: red, green, blue, red, green, blue and so on.

A state machine monitors the serial line and separates the repeating series into red, green and blue pulse trains. The state machine forwards each separate pulse train to the corresponding color element of an RGB LED. In effect, this provides each color element with a separate PWM control signal.

To ensure that the state machine and the master device operate synchronously, the master device controls the voltage on the serial line to encode a sync signal. The sync signal is a single pulse of short duration. The state machine detects the sync signal by its short duration and enters a known state. The master device may then resume the normal pattern of red, green and blue pulses. Depending on the particular implementation, it is possible for the master device to send the sync signal on a periodic basis. Alternately, the master device may be configured to detect an out-of-sync condition and send the sync signal in response.

### BRIEF DESCRIPTION OF THE DRAWINGS

FIG. 1 is a block diagram showing a master device connected to control a slave LED driver and RGB LED.

FIG. 2 is a timing diagram shown to describe the control method of the present invention.

FIG. 3 is a second timing diagram shown to describe the control method of the present invention.

FIG. 4 modifies the diagram of FIG. 1 to show a sync return signal that is generated by the slave LED driver for use by the master device.

### DETAILED DESCRIPTION OF THE PREFERRED EMBODIMENTS

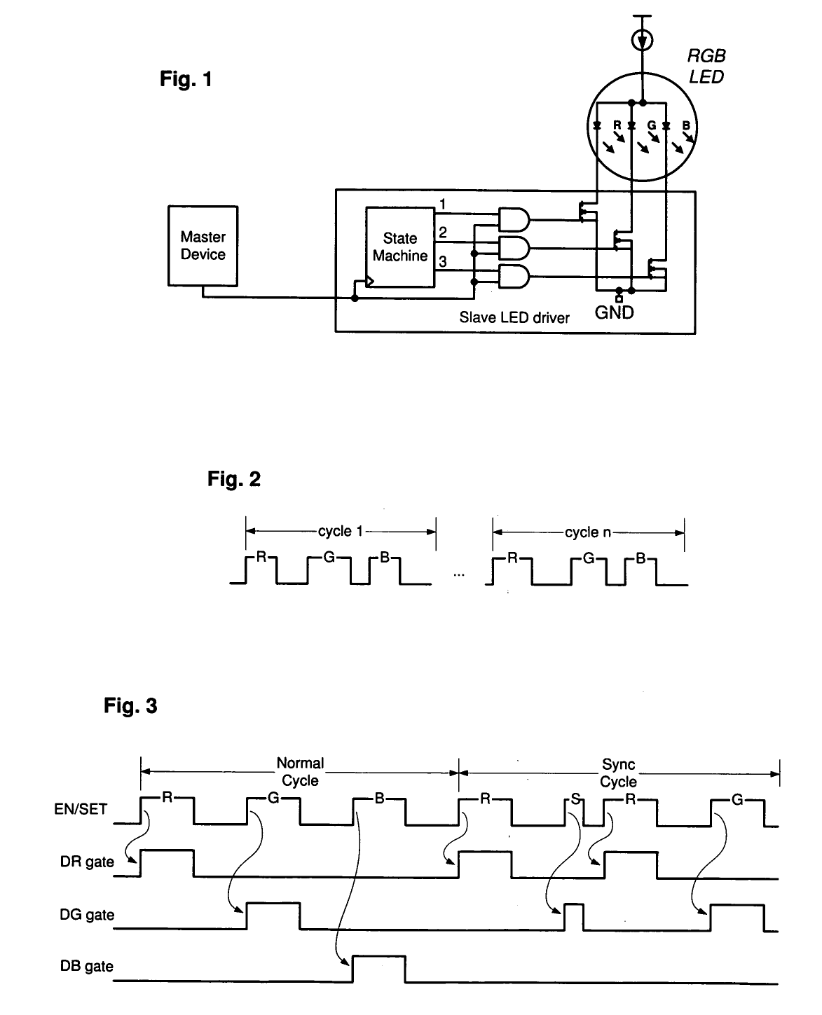

The present invention provides a method for RGB LED control using a single wire serial interface. As shown in FIG. 1, a typical implementation that uses this method includes a master device connected (via a single wire serial line) to a slave LED driver. The slave LED driver is connected, in turn to an RGB LED. Internally, the slave LED driver includes a state machine that translates signals on the serial line into signals that drive the RGB LED.

To control the RGB LED, the master device controls the voltage on the serial line to encode a repeating series of pulses. As shown in FIG. 2, the series of pulses are arranged in an interleaved pattern: red, green, blue, red, green, blue and so on. The width of each pulse is variable so, for example the red pulse in cycle n is longer than the red pulse in cycle 1. The green pulse in cycle n is also shorter than the green pulse in cycle 1.

The state machine in the slave LED driver demultiplexes this repeating pattern. The state machine uses each separate pulse to control the corresponding color element of the RGB LED. So red pulses control the red element within the RGB LED while green pulses control the green element and blue pulses control the blue element. This allows the master device to control the color and intensity produced by the RGB LED by controlling the length of the red, green and blue pulses. In effect, the pulses are separate but interleaved PWM (pulse width modulation) controls for the different LED elements.

A minimum duration referred to as T_{color} is defined for the red, green and blue pulses. In effect, that means that all pulses of this type must be longer (i.e., the serial line must be held in a high state) for at least T_{color}. The minimum duration allows the master device to encode a second type of pulse. The second type of pulse, known as a sync pulse has a duration that is less than a predetermined length referred to as T_{sync}. T_{sync} is generally defined to be less than T_{color} to prevent misidentification. Receiving a sync pulse causes the state machine to enter a known state. Typically, this state is defined to be the state where the state machine is expecting to receive a red color pulse (i.e., as is the state machine had just finished receiving a blue color pulse). This allows the master device to ensure that it and the slave LED driver operate synchronously.

FIG. 3 shows a typical interaction between the master device and slave LED driver using the method just described. In the first cycle of this interaction, the master device sends red, green and blue pulses. Because these pulses are longer than T_{color} the state machine within the slave LED driver uses them to control the red, green and blue elements within the RGB LED. For this particular example, the red, green and blue pulses are equal in length which has the effect of making the LED appear to emit white light. Changing the duration of any subset of red, green or blue pulses causes the emitted color to change. Increasing or decreasing all pulses by the same amount causes the brightness of the emitted color to increase or decrease.

The second cycle of the interaction begins with the master device sending a red color pulse to the slave LED driver. This is followed by a sync pulse. The state machine identifies the sync pulse by its short duration (i.e., less than T_{sync}). As a result, the state machine adopts the state where it is expecting a red pulse (normally after receiving a red pulse, the state machine would expect a blue pulse). As a result, the next two color pulses received by the slave LED driver are used to control green and blue LED elements, respectively.

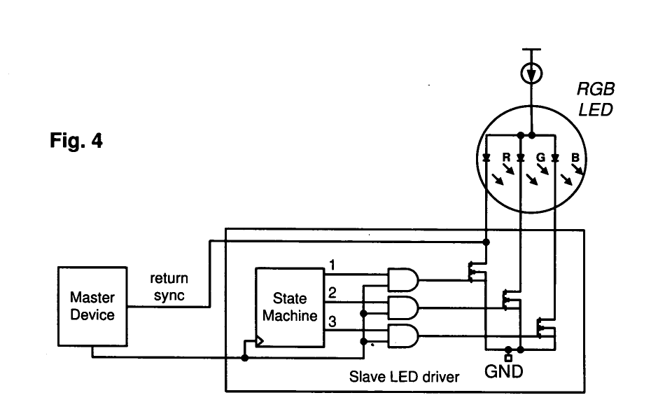

In general, the master device has the option to use the sync pulse at any convenient time. In situations where transmission errors are more likely, it makes sense to use the sync signal more often. As shown in FIG. 4, it is also possible to configure the slave LED drive to supply a sync return signal. This signal is asserted when the state machine enters the state where the red LED element is being driven. By monitoring the sync return signal, the master device may detect out of sync conditions. The master device would then respond by sending a sync pulse and resuming the normal red, green, blue pattern.

It should be noted that the preceding disclosure uses the red, green and blue sequence as an example. Other sequences of the same color are entirely equivalent (assuming that the known, post-sync state is adjusted accordingly). It is also the case that there may be different colors (e.g., cyan, yellow and magenta) or cases where more or fewer colors are multiplexed. The color pulse signals may also be used to set register levels within the slave LED driver instead of being used to directly drive the various LED elements as is shown in the implementation of FIG. 1. There may also be other devices (besides RGB LEDs) that can be controlled using the same combination of interleaved signals with sync capability.

The method just described provides an effective mechanism for controlling RGB LEDs. Importantly, it is entirely possible to use the control method as part of a more generalized device control protocol. Suitable protocols are described in U.S. patent application Ser. Nos. 10/447,764 and 10/144,333 (both incorporated in this document by reference).

The method described above has important applications for control of field sequential displays. For this application, the control signal is synchronized to the turning on and off of pixels in a monochrome LCD display to create time averaged RGB pixels. This type of display has enhanced color saturation and brightness over prior art color LCD displays that rely on color filters to create RGB pixels. The color filter has an inherent brightness/saturation tradeoff. The field sequential display allows the full LED brightness to pass unfiltered.

1. A method for controlling a device, the method comprising:
controlling the voltage on a serial line to encode a repeating series of values as voltage pulses, where each voltage pulse causes a state machine to enter a corresponding state; and
controlling the voltage on the serial line to encode a synchronization pulse, the synchronization pulse causing the state machine to enter a defined state.

2. A method as recited in claim 1 in which the series of values correspond to red, green and blue colors and in which the state machine is configured to control the elements within an RGB LED with the red, green and blue values.

3. A method as recited in claim 2 where the duration of each color value corresponds to the duration that a corresponding element within a RGB LED will be illuminated.

4. A method as recited in claim 1 in which the state machine is configured to treat all voltage pulses that are briefer than a predefined duration as synchronization pulses.

5. A method for controlling a color LED, the method comprising:
controlling the voltage on a serial line to encode the components of a color, where each component is encoded as a voltage pulse whose duration matches the intensity of that color component of the color.

6. A method as recited in claim 5 that further comprises:
activating the separate color elements within the color LED in succession, where the duration of each activation is determined by the duration of a color component encoded on the serial line.

7. A method as recited in claim 5 that further comprises:
controlling the voltage on the serial line to encode a synchronization pulse, the synchronization pulse causing the next color component encoded on the serial line to activate a predetermined color element within the color LED.

8. A method as recited in claim 5 in which the color components correspond to red, green and blue colors.

9. A method as recited in claim 5 in which the LED is part of a field segmented display.
